(19) United States
(12) Patent Application Publication
(10) Pub. No.: US 2026/0078287 A1
(43) Pub. Date: Mar. 19, 2026

(54) ADHESIVE COMPOSITION AND USES OF THE SAME

(71) Applicant: TAIWAN UNION TECHNOLOGY CORPORATION, Zhubei City (TW)

(72) Inventor: Jui-Hsiang TANG, Zhubei City (TW)

(21) Appl. No.: 19/189,608

(22) Filed: Apr. 25, 2025

(30) Foreign Application Priority Data
Sep. 16, 2024 (TW) 113135152

(51) Int. Cl. C09J 123/24; B32B 7/12; B32B 15/14; H05K 1/03

(52) U.S. Cl. CPC C09J 123/24; B32B 7/12; B32B 15/14; B32B 2311/12; B32B 2457/08; H05K 1/0366

(57) ABSTRACT

An adhesive composition is provided. The adhesive composition includes (A) a polycyclic aromatic hydrocarbon compound, (B) an olefin copolymer, and (C) a silane coupling agent. The component (B) includes the repeating units represented by the following formulas (I) to (III), and the content of the repeating unit (B-2) ranges from 1 mol % to less than 100 mol %.

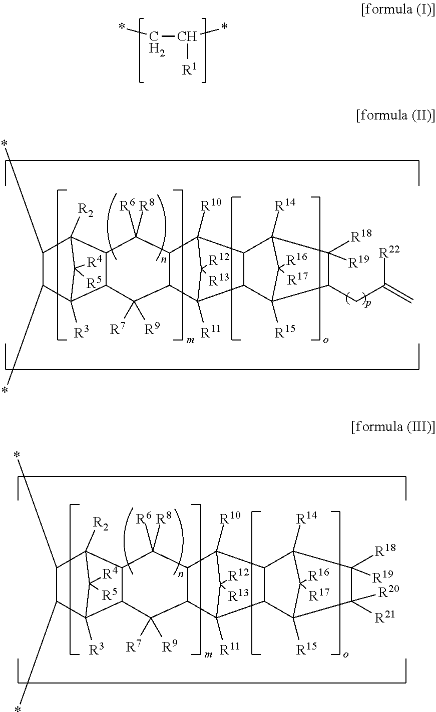

R¹ to R²¹, m, n, o, and p are as defined in the specification. Based on the total weight of the component (A), component (B) and component (C), the amount of the component (A) ranges from 33 wt % to 64 wt %, the amount of the component (B) ranges from 35 wt % to 66 wt %, and the amount of the component (C) ranges from 0.1 wt % to 4.0 wt %.

### CLAIM FOR PRIORITY

This application claims the benefit of Taiwan Patent Application No. 113135152 filed on Sep. 16, 2024, the subject matter of which are incorporated herein in their entirety by reference.

### BACKGROUND

### Field of the Invention

The present invention provides an adhesive composition, especially, an adhesive composition comprising a polycyclic aromatic hydrocarbon compound, a specific olefin copolymer and a silane coupling agent. The present invention also provides a laminate and a printed circuit board prepared from the adhesive composition.

### Descriptions of the Related Art

With the miniaturization of electronic devices, the printed circuit board is required to be thinner and denser and must meet high-frequency and high-speed transmission requirements. To achieve thinness and high-frequency/high-speed transmission, metal foils with low roughness are generally used as the conductive layers of printed circuit boards, in order to reduce space requirements and improve the electrical properties. However, the adhesion strength between a low-roughness conductive layer and a dielectric layer is poor, which in turn leads to reduced reliability of the printed circuit board.

To address the issue of low adhesion strength problem between low-roughness conductive layers and dielectric layers, U.S. Pat. No. 6,132,851 A discloses an adhesive composition for copper foils. The adhesive composition comprises at least one phenolic resole resin and a product obtained by reacting at least one di-functional epoxy resin with at least one compound represented by

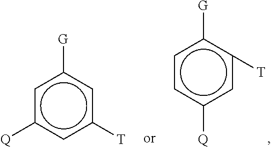

wherein G, T, and Q are each independently —COOH, —OH, —SH, —NH₂, and the like. The adhesive composition can be applied between the conductive layer and the dielectric layer to improve both adhesion strength and heat resistance. U.S. Pat. No. 7,648,770 B2 discloses a resin-containing primer in which the resin comprises a polyamideimide with a siloxane structure in its main chain. The resin primer provides improved adhesion strength between the conductor foil and the insulating layer. U.S. Pat. No. 8,519,273 B2 discloses a circuit subassembly comprising a conductive layer, a dielectric layer, and an adhesive layer. The adhesive layer, which is used between the conductive layer and the dielectric layer, includes a poly(arylene ether) to enhance the adhesion strength between the conductive layer and the circuit substrate, as well as to improve the flame retardance of the circuit subassembly. TW 1528873 B discloses a primer layer for a plating process. The primer layer contains a poly-functional epoxy resin, an epoxy resin curing agent, and a polybutadiene-modified polyamide resin containing phenolic hydroxyl groups. The primer layer exhibits high adhesion to electroless copper plating and meets the requirements for high wiring density in semiconductor packaging, while having a satisfactory solder heat resistance for a lead-free soldering process.

However, the aforementioned technical solutions still fail to fully address the issue of insufficient adhesion strength between the low roughness conductive layer and the dielectric layer in laminates.

### SUMMARY

In view of the aforementioned technical problems, the present invention provides an adhesive composition that can be used to bond the dielectric layer and the conductive layer of a laminate, thereby enhancing adhesion strength, improving the peeling strength and aging resistance of the laminate, without adversely affecting its dielectric properties, thermal resistance or dimensional stability. Accordingly, the adhesive composition of the present invention is particularly suitable for the fabrication of laminates that apply low-roughness or extremely-low-roughness metal foil as the conductive layer.

Thus, an objective of the present invention is to provide an adhesive composition, which comprises the following components:
(A) a polycyclic aromatic hydrocarbon compound;
(B) an olefin copolymer, which comprises the following repeating units:
   (B-1) a repeating unit represented by the following formula (I),

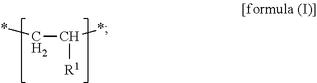

(B-2) a repeating unit represented by the following formula (II),

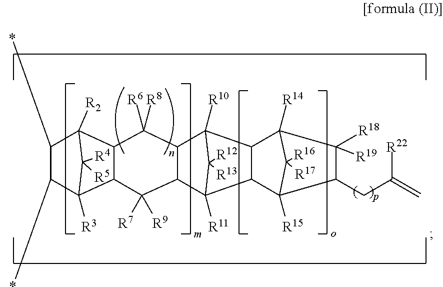

and
   (B-3) a repeating unit represented by the following formula (III),

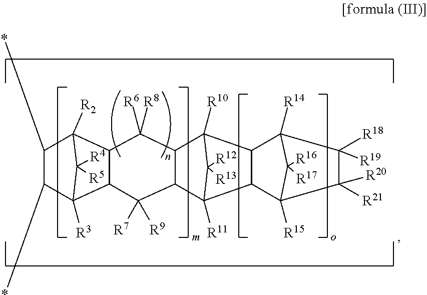

in formulas (I) to (III),
R¹ is H or a C1 to C29 linear or branched hydrocarbon group;
R² to R²¹ are independently H, halogen, a C1 to C20 alkyl, a C1 to C20 halogenated alkyl, a C3 to C15 cycloalkyl, or a C6 to C20 aryl, and R¹⁸ to R²¹ may form a monocyclic ring or polycyclic ring by binding to each other;
R²² is H or a C1 to C10 alkyl;
m and n are independently 0 or 1;
is 0 or a positive integer;
p is 0 or a positive integer ranging from 1 to 10; and
in formula (III), when both m and n are 0, at least one of R¹⁰ to R¹³ and R¹⁸ to R²¹ is not H; and
(C) a silane coupling agent,
wherein,
based on the total moles of the repeating units (B-1), (B-2) and (B-3), the amount of the repeating unit (B-2) ranges from 1 mol % to less than 100 mol %; and
based on the total weight of the polycyclic aromatic hydrocarbon compound (A), the olefin copolymer (B) and the silane coupling agent (C), the amount of the polycyclic aromatic hydrocarbon compound (A) ranges from 33 wt % to 64 wt %, the amount of the olefin copolymer (B) ranges from 35 wt % to 66 wt %, and the amount of the silane coupling agent (C) ranges from 0.1 wt % to 4.0 wt %.

In one embodiment of the present invention, the polycyclic aromatic hydrocarbon compound (A) is selected from the group consisting of acenaphthylene, biphenyl, naphthalene, anthracene, phenanthrene, pyrene, benzo[a]pyrene, benzo[e]pyrene, indeno[1,2,3-cd]pyrene, benzo[a]anthracene, fluoranthene, benzo[b]fluoranthene, benzo[g,h,i]fluoranthene, benzo[j]fluoranthene, benzo[k]fluoranthene, chrysene, 5-methylchrysene, dibenzo[a,h]anthracene, perylene, benzo[g,h,i]perylene, acenaphthene, fluorene, ovalene, and combinations thereof.

In one embodiment of the present invention, the polycyclic aromatic hydrocarbon compound (A) has from two to ten aromatic rings, preferably from two to four aromatic rings.

In one embodiment of the present invention, based on the total weight of the polycyclic aromatic hydrocarbon compound (A), the olefin copolymer (B) and the silane coupling agent (C), the amount of the polycyclic aromatic hydrocarbon compound (A) ranges from 34 wt % to 56 wt %.

In one embodiment of the present invention, R¹ is H or a C1 to C6 alkyl.

In one embodiment of the present invention, the repeating unit (B-2) is formed by addition copolymerization of one or more cyclic non-conjugated diene monomers, wherein the one or more cyclic non-conjugated diene monomers are selected from the group consisting of

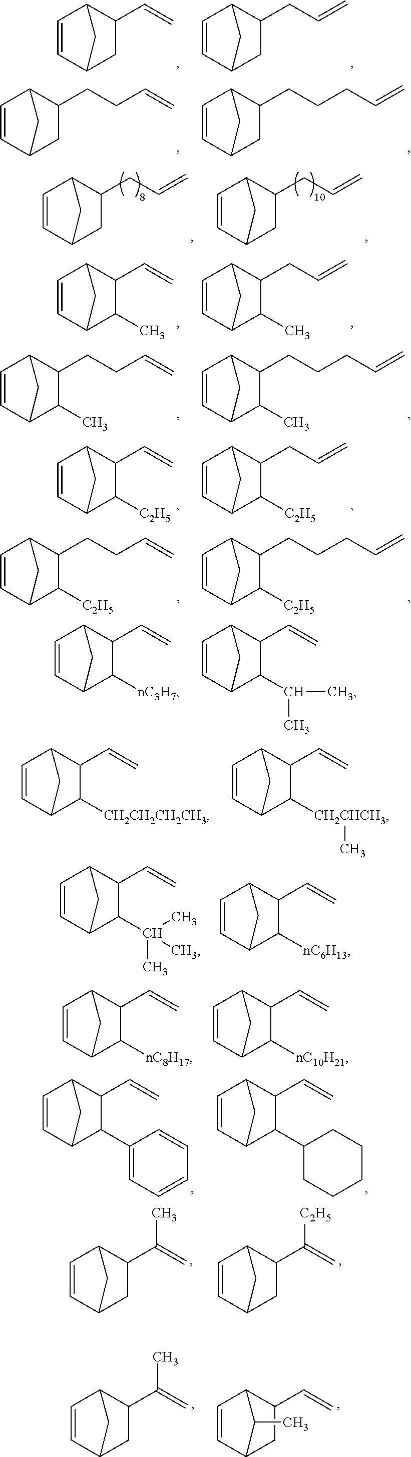

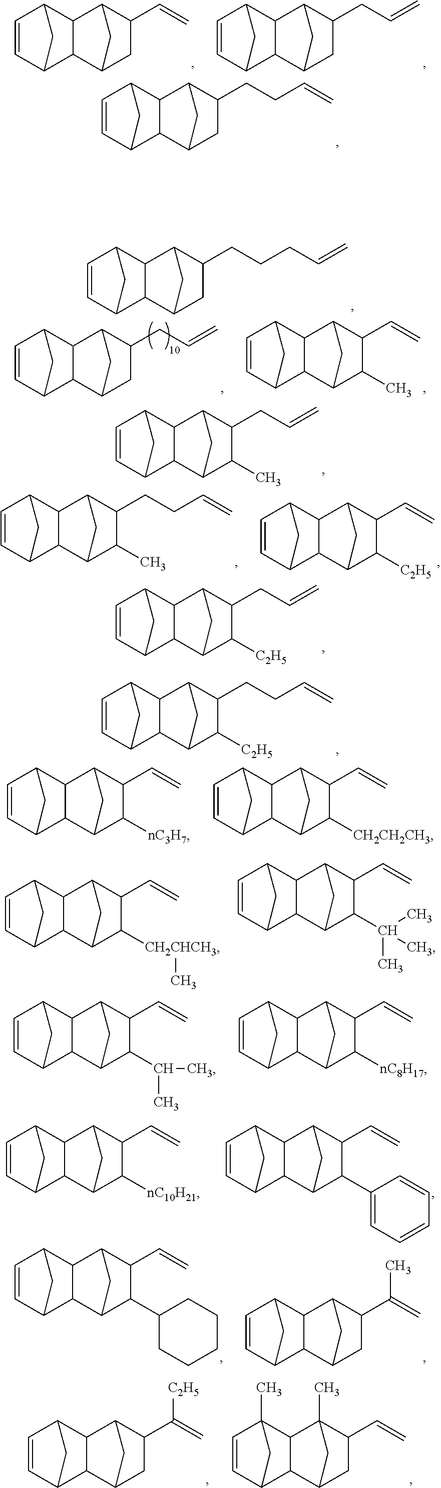

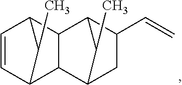

and combinations thereof.

In one embodiment of the present invention, based on the total moles of the repeating units (B-1), (B-2) and (B-3), the amount of the repeating unit (B-2) ranges from 19 mol % to 36 mol %.

In one embodiment of the present invention, based on the total weight of the polycyclic aromatic hydrocarbon compound (A), the olefin copolymer (B) and the silane coupling agent (C), the amount of the olefin copolymer (B) ranges from 42 wt % to 65 wt %.

In one embodiment of the present invention, the silane coupling agent (C) is an amino silane coupling agent.

In one embodiment of the present invention, the silane coupling agent (C) is selected from the group consisting of N-(2-aminoethyl)-3-aminopropyl trimethoxy silane, N-(n-butyl)-3-aminopropyl trimethoxy silane, N-phenyl-3-aminopropyl trimethoxy silane, 3-methacryloxy propyl trimethoxy silane, 4-epoxypropyl butyl trimethoxy silane, vinyl trimethoxy silane, vinyl phenyl trimethoxy silane, 3-mercaptopropyl methyl dimethoxy silane, 3-mercaptopropyl trimethoxy silane, tetraethoxysilane, and combinations thereof.

In one embodiment of the present invention, based on the total weight of the polycyclic aromatic hydrocarbon compound (A), the olefin copolymer (B) and the silane coupling agent (C), the amount of the silane coupling agent (C) ranges from 2.0 wt % to 4.0 wt %.

Another objective of the present invention is to provide a laminate, which comprises:
a dielectric layer;
an adhesive layer disposed on at least one side of the dielectric layer; and
a conductive layer disposed on the other side of the adhesive layer opposite to the dielectric layer,
wherein the adhesive layer is formed from the aforementioned adhesive composition.

In one embodiment of the present invention, the conductive layer is a copper foil.

In one embodiment of the present invention, the dielectric layer is prepared from one or more prepregs, wherein each of the prepregs comprises a curable resin and a reinforcing material.

In one embodiment of the present invention, the curable resin is selected from the group consisting of polyphenylene ether resins, epoxy resins, phenolic resins, polyformaldehyde resins, silicones, multi-functional vinyl aromatic copolymers, polytetrafluoroethylene, and combinations thereof.

Yet another objective of the present invention is to provide a printed circuit board that is prepared from the aforementioned laminate.

To render the above objectives, technical features and advantages of the present invention more apparent, the present invention will be described in detail with reference to some embodiments hereinafter.

### BRIEF DESCRIPTION OF THE DRAWINGS

FIG. 1 is a schematic diagram showing an embodiment of the laminate of the present invention.

FIG. 2 is a schematic diagram showing another embodiment of the laminate of the present invention.

FIG. 3 is a schematic diagram showing an embodiment of the printed circuit board of the present invention.

FIG. 4 is a schematic diagram showing another embodiment of the printed circuit board of the present invention.

### DETAILED DESCRIPTION

Hereinafter, some embodiments of the present invention will be described in detail. However, the present invention may be embodied in various embodiments and should not be limited to the embodiments described in the specification.

In the appended drawings, similar elements are denoted by similar reference numerals. The thickness of each layer and region may be exaggerated for clarity. Unless it is additionally explained, when a layer is described as being “on” another layer or a substrate, the layer can be directly on the other layer or the substrate, or intervening layer(s) may also be present.

Unless otherwise specified, the expressions “a,” “the,” or the like recited in the specification and in the claims should include both the singular and the plural forms.

Unless otherwise specified, the terms “first”, “second” or similar expressions used in the specification and claims are employed solely for the purpose of distinguishing the depicted elements or components without any specific significance. Those terms are not intended to imply priority.

Unless otherwise specified, while describing the amount of the components in the solution, mixture, composition or varnish in the specification and in the claims, the weight of the solvent is not included.

As used herein, the term “polycyclic aromatic hydrocarbon compound” refers to a hydrocarbon compound that does not contain heteroatoms or substituents and includes a structure having at least two aromatic rings. The structure comprising at least two aromatic rings also encompasses fused ring structures in which two or more carbon atoms are shared between aromatic rings.

As used herein, the term “curable resin” refers not only to the curable resin itself as individually listed, but also to resin compositions comprising the curable resin in any combination with other known components.

The adhesive composition of the present invention uses a polycyclic aromatic hydrocarbon compound, a specific olefin copolymer and a silane coupling agent in combination in a specific ratio, such that the resulting laminate produced using the adhesive composition exhibits excellent peeling strength and aging resistance without adversely affecting its dielectric properties, thermal resistance, or dimensional stability. This allows the laminate to meet the requirements of thin printed circuit boards and high-frequency/high-speed transmission printed circuit boards. Detailed descriptions of the adhesive composition of the present invention and its applications are elaborated below.

### 1. Adhesive Composition

The adhesive composition comprises a polycyclic aromatic hydrocarbon compound (A), a specific olefin copolymer (B) and a silane coupling agent (C) as essential components, and other optional components. Detailed descriptions of each component are provided below.

### 1.1. Polycyclic Aromatic Hydrocarbon Compound (A)

In adhesive composition of the present invention, the polycyclic aromatic hydrocarbon compound (A) refers to a hydrocarbon compound that does not contain heteroatoms or substituents and includes a structure having at least two aromatic rings. In one embodiment of the present invention, the polycyclic aromatic hydrocarbon compound (A) is free of vinyl groups.

In one embodiment of the present invention, examples of the polycyclic aromatic hydrocarbon compound (A) include, but are not limited to, acenaphthylene, biphenyl, naphthalene, anthracene, phenanthrene, pyrene, benzo[a]pyrene, benzo[e]pyrene, indeno[1,2,3-cd]pyrene, benzo[a]anthracene, fluoranthene, benzo[b]fluoranthene, benzo[g,h,i]fluoranthene, benzo[j]fluoranthene, benzo[k]fluoranthene, chrysene, 5-methylchrysene, dibenzo[a,h]anthracene, perylene, benzo[g,h,i]perylene, acenaphthene, fluorene, and ovalene. Each of the aforementioned polycyclic aromatic hydrocarbon compounds may be used individually or in any combination.

In one preferred embodiment of the present invention, the polycyclic aromatic hydrocarbon compound (A) has from two to ten aromatic rings, preferably from two to four aromatic rings. For example, the polycyclic aromatic hydrocarbon compound (A) can have two aromatic rings, three aromatic rings, or four aromatic rings. Examples of the polycyclic aromatic hydrocarbon compound (A) with two aromatic rings include, but are not limited to, biphenyl, naphthalene, acenaphthene, and acenaphthylene. Examples of the polycyclic aromatic hydrocarbon compound (A) with three aromatic rings include, but are not limited to, anthracene, phenanthrene, and fluoranthene. Examples of the polycyclic aromatic hydrocarbon compound (A) with four aromatic rings include, but are not limited to, chrysene, perylene, and pyrene. In the appended examples, acenaphthylene, naphthalene, phenanthrene or biphenyl is used as the polycyclic aromatic hydrocarbon compound (A).

In the adhesive composition of the present invention, based on the total weight of the polycyclic aromatic hydrocarbon compound (A), the olefin copolymer (B) and the silane coupling agent (C), the amount of the polycyclic aromatic hydrocarbon compound (A) may range from 33 wt % to 64 wt %. For example, based on the total weight of the polycyclic aromatic hydrocarbon compound (A), the olefin copolymer (B) and the silane coupling agent (C), the amount of the polycyclic aromatic hydrocarbon compound (A) may be 33 wt %, 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, or 64 wt %, or within a range between any two of the values described herein. In one preferred embodiment of the present invention, based on the total weight of the polycyclic aromatic hydrocarbon compound (A), the olefin copolymer (B) and the silane coupling agent (C), the amount of the polycyclic aromatic hydrocarbon compound (A) ranges from 34 wt % to 56 wt %. If the amount of the polycyclic aromatic hydrocarbon compound (A) is lower than the specified range, the resultant laminate has poor aging resistance. If the amount of the polycyclic aromatic hydrocarbon compound (A) is higher than the specified range, the resultant laminate has poor peeling strength and poor aging resistance.

### 1.2. Olefin Copolymer (B)

In the adhesive composition of the present invention, the olefin copolymer (B) contains cross-linkable group(s). The olefin copolymer (B) comprises a repeating unit (B-1) represented by the following formula (I), a repeating unit (B-2) represented by the following formula (II), and a repeating unit (B-3) represented by the following formula (III).

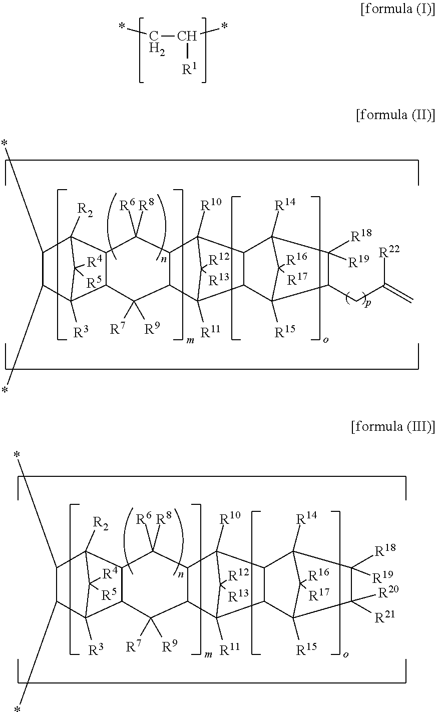

In formula (I), R¹ is H or a C1 to C29 linear or branched hydrocarbon group, preferably H or a C1 to C29 linear or branched alkyl, and more preferably H or a C1 to C6 linear or branched alkyl. Examples of the C1 to C6 linear or branched alkyl include, but are not limited to, methyl, ethyl, n-propyl, isopropyl, n-butyl, isobutyl, tert-butyl, n-pentyl, isopentyl, tert-pentyl, neopentyl, n-hexyl, and isohexyl.

In formula (II), R² to R¹⁹ may be identical or different, and may independently be H, halogen, a C1 to C20 alkyl, a C1 to C20 halogenated alkyl, a C3 to C15 cycloalkyl, or a C6 to C20 aryl, wherein R¹⁸ and R¹⁹ may form a monocyclic ring or polycyclic ring by binding to each other. R²² is H or a C1 to C10 alkyl; m and n are independently 0 or 1; o is 0 or a positive integer, preferably an integer ranging from 0 to 50, and more preferably an integer ranging from 0 to 20; and p is an integer ranging from 0 to 10. It is preferred that R² to R¹⁹ are independently H, a C1 to C10 alkyl, a C3 to C8 cycloalkyl, or a C6 to C12 aryl; R²² is H or a C1 to C6 alkyl; and o is 0, 1 or 2. Examples of the C1 to C10 alkyl include, but are not limited to, the C1 to C6 alkyl groups described above. Examples of the C3 to C8 cycloalkyl include, but are not limited to, cyclopropyl, cyclobutyl, cyclopentyl, cyclohexyl, cycloheptyl, and cyclooctyl. Examples of the C6 to C12 aryl include, but are not limited to, phenyl, biphenyl, and naphthyl.

In formula (III), R² to R¹⁹, m, n, o, and p are as defined above. R²⁰ and R²¹ may be identical or different, and may independently be H, halogen, a C1 to C20 alkyl, a C1 to C20 halogenated alkyl, a C3 to C15 cycloalkyl, or a C6 to C20 aryl, wherein R¹⁸ to R²¹ may form a monocyclic ring or polycyclic ring by binding to each other. In formula (III), when both m and n are 0, at least one of R¹⁰ to R¹³ and R¹⁸ to R²¹ is not H. Examples of the C1 to C20 alkyl include, but are not limited to, the C1 to C6 alkyl groups described above. Examples of the C3 to C15 cycloalkyl include, but are not limited to, the C3 to C8 cycloalkyl groups described above. Examples of the C6 to C20 aryl include, but are not limited to, the C6 to C12 aryl groups described above.

Based on the total weight of the polycyclic aromatic hydrocarbon compound (A), the olefin copolymer (B) and the silane coupling agent (C), the amount of the olefin copolymer (B) may be 35 wt % to 66 wt %. For example, based on the total weight of the polycyclic aromatic hydrocarbon compound (A), the olefin copolymer (B) and the silane coupling agent (C), the amount of the olefin copolymer (B) may be 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, or 66 wt %, or within a range between any two of the values described herein. In the preferred embodiments of the present invention, based on the total weight of the polycyclic aromatic hydrocarbon compound (A), the olefin copolymer (B) and the silane coupling agent (C), the amount of the olefin copolymer (B) ranges from 42 wt % to 65 wt %. If the amount of the olefin copolymer (B) is lower than the specified range, the resultant laminate has poor peeling strength and poor aging resistance. If the amount of the olefin copolymer (B) is higher than the specified range, the resultant laminate has poor aging resistance.

The method for preparing the olefin copolymer (B) may refer to, for example, U.S. Pat. No. 9,206,278 B2, and the entire contents of which are incorporated herein by reference.

### [Repeating Unit (B-1)]

The repeating unit (B-1) represented by formula (I) is formed by addition copolymerization of one or more monomers represented by the following formula (I-1), wherein R¹ is as defined above.

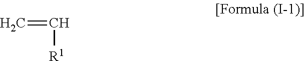

Examples of the monomers represented by formula (I-1) include, but are not limited to, ethylene, propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, and 1-eicosene. Each of the aforementioned monomers represented by formula (I-1) can be used individually or in any combination. In the appended examples, the repeating unit (B-1) represented by formula (I) is formed by addition copolymerization of ethylene.

### [Repeating Unit (B-2)]

The repeating unit (B-2) represented by formula (II) is formed by addition copolymerization of one or more cyclic non-conjugated diene monomers represented by the following formula (II-1), wherein R² to R¹⁹, R²², m, n, o, and p are as defined above.

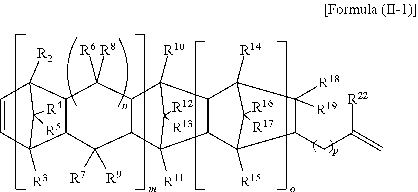

Examples of the cyclic non-conjugated diene monomers represented by formula (II-1) include, but are not limited to,

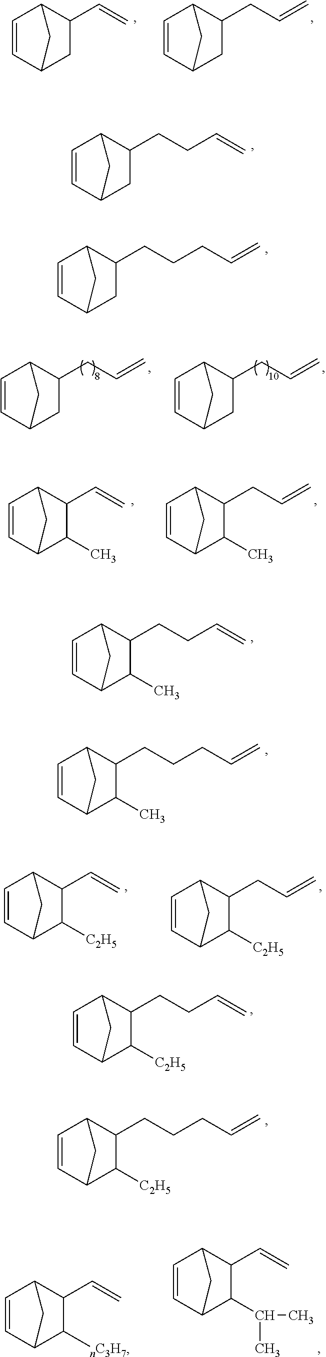

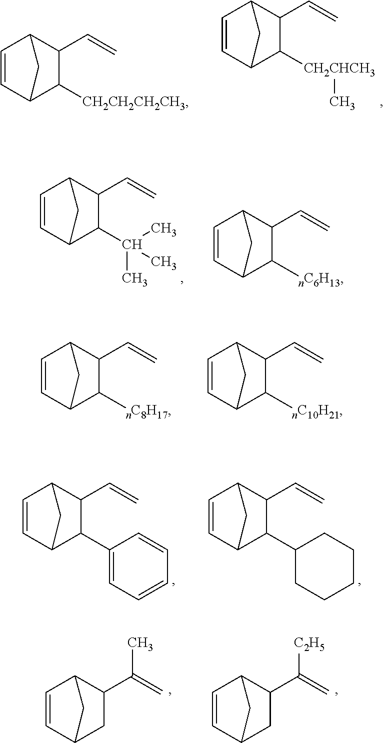

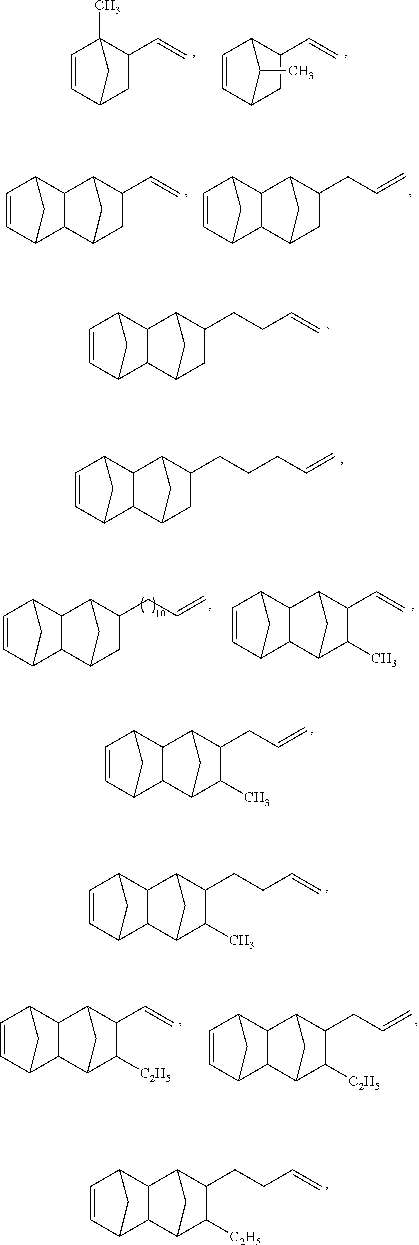

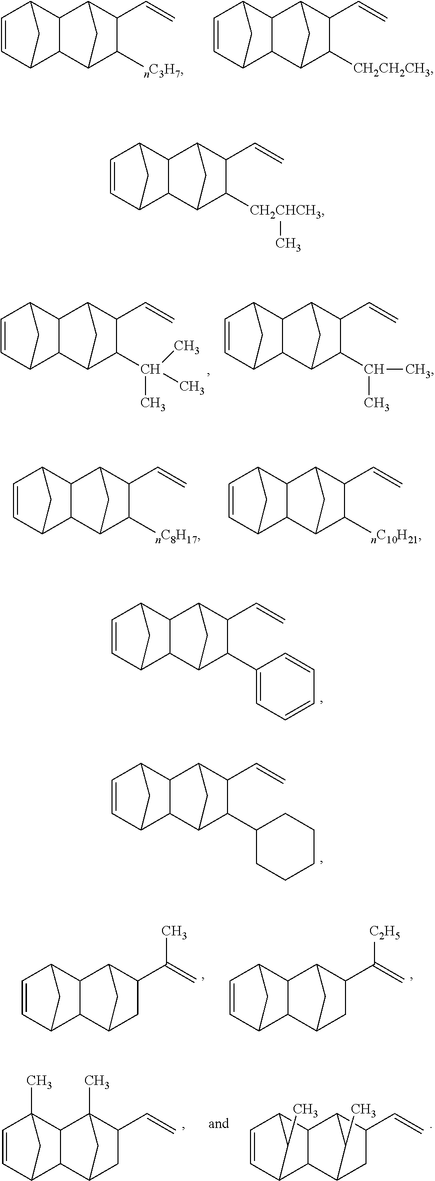

Each of the aforementioned cyclic non-conjugated diene monomers represented by formula (II-1) can be used individually or in any combination. In the appended examples, the repeating unit (B-2) represented by formula (II) is formed by addition copolymerization of 5-vinyl-2-norbornene

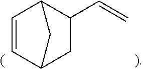

In the olefin copolymer (B), based on the total moles of the repeating units (B-1), (B-2) and (B-3), the amount of the repeating unit (B-2) ranges from 1 mol % to less than 100 mol %, preferably from 19 mol % to 36 mol %, and more preferably from 20 mol % to 33 mol %. When the amount of the repeating unit (B-2) falls within the specified range, the olefin copolymer (B) can impart long-term stable dielectric properties and excellent thermal resistance to the adhesive composition, while also providing an excellent balance between mechanical properties and dielectric properties.

### [Repeating Unit (B-3)]

The repeating unit (B-3) represented by formula (III) is formed by addition copolymerization of one or more cyclic olefin monomers represented by the following formula (III-1), wherein R² to R²¹, m, n, o, and p areas defined above.

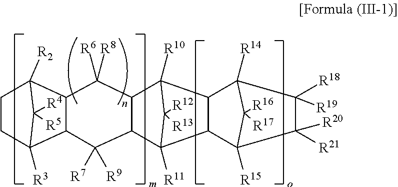

Examples of the cyclic olefin monomers represented by formula (III-1) include, but are not limited to, bicyclo[2.2.1]-2-heptene (norbornene,

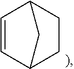

and tetracyclo[[4.4.0.1^{2.5}.1^{7,10}]-3-dodecene (tetracyclododecene,

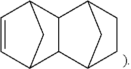 [SMILES: C1=CC2CC1C1C3CCC(C3)C21]

In the appended examples, the repeating unit (B-3) represented by formula (III) is formed by addition copolymerization of bicyclo[2.2.1]-2-heptene or tetracyclo[[4.4.0.1^{2.5}.1^{7,10}]-3-dodecene.

In the olefin copolymer (B), based on the total moles of the repeating units (B-1), (B-2) and (B-3), the amount of the repeating unit (B-3) ranges from 0.1 mol % to less than 100 mol %, preferably from 0.1 mol % to 50 mol %, and more preferably from 1 mol % to 20 mol %. When the amount of the repeating unit (B-3) falls within the specified range, the olefin copolymer (B) can maintain a proper elastic modulus and its cross-linking reaction can be easily controlled.

### [Optional Repeating Unit]

In the adhesive composition of the present invention, in addition to the aforementioned repeating units (B-1), (B-2) and (B-3), the olefin copolymer (B) may further comprise one or more repeating units formed by addition copolymerization of other cyclic olefin monomers and/or linear olefin polyene monomers. The other cyclic olefin monomers exclude the cyclic non-conjugated diene monomers represented by formula (II-1) and the cyclic olefin monomers represented by formula (III-1).

### 1.3. Silane Coupling Agent (C)

The silane coupling agent can facilitate the formation of covalent bonds within the adhesive composition, or form part of such covalent bonds, thereby further improving the adhesion performance of the adhesive composition. Examples of silane coupling agents include, but are not limited to, olefin-functional silanes, epoxy-functional silanes, vinyl-functional silanes, propenyl-functional silanes, amino-functional silanes, and mercapto-functional silanes, with amino-functional silanes being preferred. The silane coupling agent may be represented by the following formula (IV).

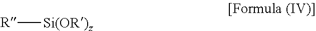

In formula (IV), R″ is an organic functional group, such as amino, vinyl, mercapto, phenyl, epoxy, acryloyl, and the like; OR′ is a hydrolysable group, such as methoxy or ethoxy; and z is 2 or 3.

In one embodiment of the present invention, the silane coupling agent (C) is selected from the group consisting of N-(2-aminoethyl)-3-aminopropyl trimethoxy silane, N-(n-butyl)-3-aminopropyl trimethoxy silane, N-phenyl-3-aminopropyl trimethoxy silane, 3-methacryloxy propyl trimethoxy silane, 4-epoxypropyl butyl trimethoxy silane, vinyl trimethoxy silane, vinyl phenyl trimethoxy silane, 3-mercaptopropyl methyl dimethoxy silane, 3-mercaptopropyl trimethoxy silane, tetraethoxysilane, and mixtures thereof.

The silane coupling agent (C) are commercially available. For example, the silane coupling agent (C) can be: the products available from SHIN-ETSU CHEMICAL, such as KBM-503 (3-methacryloxy propyl trimethoxy silane), KBM-603 (N-(2-aminoethyl)-3-aminopropyl trimethoxy silane) and KBM-1003 (vinyl trimethoxy silane); or the products available from Evonik, such as Dynasylan 1189 (N-(n-butyl)-3-aminopropyl trimethoxy silane), Dynasylan 1146 (N-(2-aminoethyl)-3-aminopropyl trimethoxy silane), Dynasylan MEMO (3-methacryloxy propyl trimethoxy silane), and Dynasylan VTMO (vinyl trimethoxy silane). In the appended examples, N-(n-butyl)-3-aminopropyl trimethoxy silane, N-(2-aminoethyl)-3-aminopropyl trimethoxy silane, 3-methacryloxy propyl trimethoxy silane and vinyl trimethoxy silane are used as the silane coupling agent (C).

Based on the total weight of the polycyclic aromatic hydrocarbon compound (A), the olefin copolymer (B) and the silane coupling agent (C), the amount of the silane coupling agent (C) may be from 0.1 wt % to 4.0 wt %. For example, based on the total weight of the polycyclic aromatic hydrocarbon compound (A), the olefin copolymer (B) and the silane coupling agent (C), the amount of the silane coupling agent (C) may be 0.1 wt %, 0.2 wt %, 0.3 wt %, 0.4 wt %, 0.5 wt %, 0.6 wt %, 0.7 wt %, 0.8 wt %, 0.9 wt %, 1.0 wt %, 1.1 wt %, 1.2 wt %, 1.3 wt %, 1.4 wt %, 1.5 wt %, 1.6 wt %, 1.7 wt %, 1.8 wt %, 1.9 wt %, 2.0 wt %, 2.1 wt %, 2.2 wt %, 2.3 wt %, 2.4 wt %, 2.5 wt %, 2.6 wt %, 2.7 wt %, 2.8 wt %, 2.9 wt %, 3.0 wt %, 3.1 wt %, 3.2 wt %, 3.3 wt %, 3.4 wt %, 3.5 wt %, 3.6 wt %, 3.7 wt %, 3.8 wt %, 3.9 wt %, or 4.0 wt %, or within a range between any two of the values described herein. In the preferred embodiments of the present invention, based on the total weight of the polycyclic aromatic hydrocarbon compound (A), the olefin copolymer (B) and the silane coupling agent (C), the amount of the silane coupling agent (C) ranges from 2.0 wt % to 4.0 wt %.

### 1.4. Other Components

The adhesive composition of the present invention can optionally further comprise other components, such as additives known in the art, to improve the physicochemical properties of the laminate manufactured by using the adhesive composition or the processability of the adhesive composition during the manufacturing process. Examples of the known additives include, but are not limited to, a flame retardant, a viscosity modifier, a thixotropic agent, a defoaming agent, a leveling agent, a surface treating agent, a stabilizer, and an anti-oxidant. The method of use and the amount of such additives are within the routine knowledge of persons having ordinary skill in the art, and may be adjusted as needed after reviewing the present disclosure.

In one embodiment of the present invention, the adhesive composition further comprises a flame retardant. Examples of the flame retardant include, but are not limited to, a phosphorus-containing flame retardant and a bromine-containing flame retardant. Examples of the phosphorus-containing flame retardant include, but are not limited to, phosphate esters, phosphazenes, ammonium polyphosphates, and melamine phosphates. Examples of the bromine-containing flame retardant include, but are not limited to, tetrabromobisphenol A, decabromodiphenyloxide, decabrominated diphenyl ethane, 1,2-bis(tribromophenyl) ethane, brominated epoxy oligomer, octabromotrimethylphenyl indane, bis(2,3-dibromopropyl ether), tris(tribromophenyl) triazine, brominated aliphatic hydrocarbon, and brominated aromatic hydrocarbon. The aforementioned flame retardants can be used individually or in any combination.

### 1.5. Preparation of Adhesive Composition

The adhesive composition of the present invention may be prepared into varnish form for subsequent applications by evenly mixing each of the components of the adhesive composition, including the polycyclic aromatic hydrocarbon compound (A), the olefin copolymer (B), the silane coupling agent (C), and other optional constituents, through a stirrer and dissolving or dispersing the resultant mixture into a solvent. The solvent can be any inert solvent that can dissolve or disperse the components of the adhesive composition, but does not react with these components. For example, the solvent which can dissolve or disperse the components of the adhesive composition include, but are not limited to, benzene, toluene, xylene, hexane, cyclohexane, heptane, and decane. The aforementioned solvents can be used individually or in any combination. The amount of the solvent is not particularly limited as long as the components of the adhesive composition can be evenly dissolved or dispersed therein. In the appended examples, toluene is used as the solvent.

### 2. Laminate

The present invention also provides a laminate prepared from the aforementioned adhesive composition. The laminate comprises a dielectric layer, an adhesive layer disposed on at least one side of the dielectric layer, and a conductive layer disposed on the other side of the adhesive layer opposite to the dielectric layer, wherein the adhesive layer is formed from the aforementioned adhesive composition. In the laminate of the present invention, the constitution of the adhesive composition for forming the adhesive layer can be different from the constitution of the resin composition for forming the dielectric layer. The laminate may also be referred to as a metal-clad laminate.

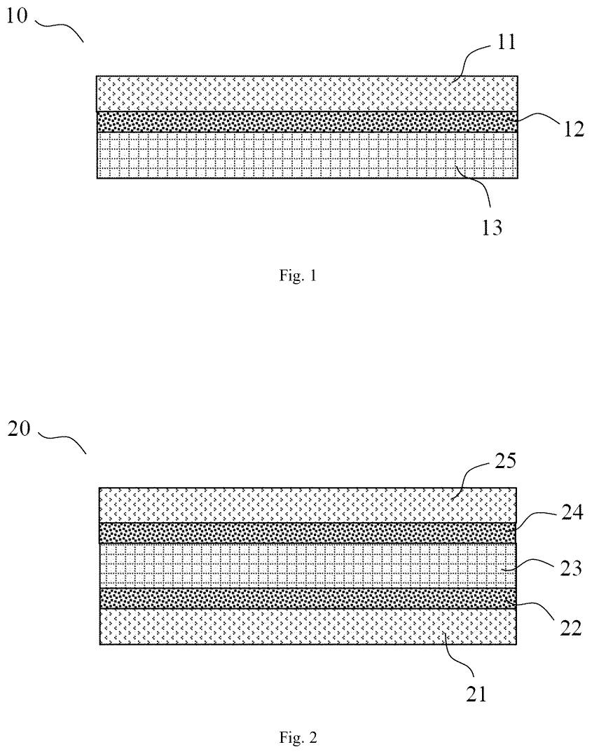

FIG. 1 is a schematic diagram showing an embodiment of the laminate of the present invention. As shown in FIG. 1, the laminate 10 comprises a conductive layer 11, an adhesive layer 12, and a dielectric layer 13, wherein the adhesive layer 12 is formed from the adhesive composition of the present invention and is disposed between the conductive layer 11 and the dielectric layer 13. For example, the conductive layer 11 may be a copper foil, and the adhesive layer 12 and the dielectric layer 13 may be independently in a semi-cured state or in a cured state.

FIG. 2 is a schematic diagram showing another embodiment of the laminate of the present invention. As shown in FIG. 2, the laminate 20 comprises a first conductive layer 21, a first adhesive layer 22, a dielectric layer 23, a second adhesive layer 24, and a second conductive layer 25, wherein the first adhesive layer 22 is disposed between the first conductive layer 21 and the dielectric layer 23, and the second adhesive layer 24 is disposed between the dielectric layer 23 and the second conductive layer 25. The first conductive layer 21 and the second conductive layer 25 may be an identical or different metal foils, and the metal foil may be, for example, a copper foil. The first adhesive layer 22 and the second adhesive layer 24 may be formed from the adhesive compositions of the present invention, using either the same or different formulations. In addition, the laminate 20 may include only the first adhesive layer 22 or only the second adhesive layer 24.

### [Conductive Layer]

In the laminate of the present invention, examples of the material that can be used to form the conductive layer include, but are not limited to, copper, stainless steel, aluminum, zinc, iron, nickel, gold, silver, a transition metal, and an alloy of two or more of aforementioned metals. Specific examples of the conductive layer include, but are not limited to, a conducive metal foil, preferably a copper foil.

The surface of the copper foil may be smooth or roughened to have a rough surface. Examples of copper foil include, but are not limited to, a high temperature elongation (HTE) copper foil (surface roughness Ra: 6 μm to 10 μm), a reverse treatment foil (RTF) (surface roughness Ra: 2 μm to 5 μm), a very low profile (VLP) copper foil (surface roughness Ra: less than 2 μm), and a hyper very low profile (HVLP) copper foil (surface roughness Ra: less than 1.5 μm). In the appended examples, an HVLP copper foil is used.

### [Dielectric Layer]

In the laminate of the present invention, the dielectric layer is prepared from one or more prepregs. The prepreg may be prepared by impregnating a reinforcing material with a curable resin or by coating a curable resin onto a reinforcing material, and then drying the impregnated or coated reinforcing material. Alternatively, the prepreg may be prepared by directly coating a curable resin onto a substrate and drying the curable resin to form a resin sheet, and then removing the resin sheet from the substrate. Examples of the curable resin include, but are not limited to, polyphenylene ether resins, epoxy resins, phenolic resins, polyformaldehyde resins, silicones, multi-functional vinyl aromatic copolymers, and polytetrafluoroethylene. Each of the aforementioned curable resins can be used individually or in any combination. Examples of the reinforcing material include, but are not limited to, glass fiber fabrics, glass fiber mats, insulating papers, and linen fabrics. In the appended examples, multi-functional vinyl aromatic copolymers are used as curable resin, and glass fiber fabrics are used as reinforcing material.

The multi-functional vinyl aromatic copolymer may be obtained by copolymerization of one or more divinyl aromatic compounds, one or more monovinyl aromatic compounds, and other optional monomers. As used herein, a divinyl aromatic compound refers to an aromatic compound with two vinyl groups. Examples of the divinyl aromatic compound include, but are not limited to, divinylbenzene, divinylnaphthalene, divinyl-biphenyl, and isomers thereof. Each of the aforementioned divinyl aromatic compounds can be used individually or in any combination. As used herein, a monovinyl aromatic compound refers to an aromatic compound with one vinyl group. Examples of the monovinyl aromatic compound include, but are not limited to, a nuclear-alkyl-substituted vinyl aromatic compound, an α-alkyl-substituted vinyl aromatic compound, a β-alkyl-substituted vinyl aromatic compound, and an alkoxy-substituted vinyl aromatic compound. Each of the aforementioned monovinyl aromatic compounds can be used individually or in any combination.

In addition, examples of the other optional monomers useful for preparing the multi-functional vinyl aromatic copolymer include, but are not limited to, trivinyl aromatic compounds, trivinyl aliphatic compounds, divinyl aliphatic compounds, and monovinyl aliphatic compounds. It should be noted that based on the total molar amount of the divinyl aromatic compounds, monovinyl aromatic compounds and the optionally used other monomers, the content of the optionally used other monomers is preferably not higher than 50 mol %, and more preferably not higher than 30 mol %. In other words, in the multi-functional vinyl aromatic copolymer, the polymerization units derived from the divinyl aromatic compounds and monovinyl aromatic compounds preferably constitute the majority.

### [Adhesive Layer]

In the laminate of the present invention, the adhesive layer is formed from the adhesive composition of the present invention and disposed between the conductive layer and the dielectric layer. The adhesive layer improves the adhesion strength between the conductive layer and the dielectric layer. The adhesive layer may be formed by applying the adhesive composition between the conductive layer and the dielectric layer by using coating methods known in the art and then drying the applied adhesive composition. Examples of the coating methods include screen printing, roller coating, die coating, dip coating, spray coating, and the like.

The laminate of the present invention, through the use of a specific adhesive layer, can enhance the adhesion strength between the conductive layer and the dielectric layer without altering the formulation of the dielectric layer. In other words, the constitution of the adhesive layer can be different from the constitution of the dielectric layer, thereby imparting flexibility to the laminate itself. In addition, the thickness of the adhesive layer preferably ranges from 0.1 μm to 10 μm, and more preferably from 0.1 μm to 2 μm. Within the specified thickness range, excellent adhesion strength can be provided without affecting other properties of the laminate, thereby improving the peeling strength characteristics of the laminate.

### [Preparation of Laminate]

The laminate of the present invention may be prepared as below. First, providing a conducive layer and a dielectric layer. Then, providing an adhesive layer between the conductive layer and the dielectric layer for adhering the conductive layer to the dielectric layer, wherein the adhesive layer is formed from the aforementioned adhesive composition. Specifically, the laminate may be obtained by coating the adhesive composition onto at least one of the conductive layer and dielectric layer, superimposing the dielectric layer and the conductive layer to form a structure that sequentially includes the conductive layer, the adhesive composition layer and the dielectric layer, and hot-pressing the superimposed object. Alternatively, the laminate may be obtained by forming the adhesive composition into an adhesive layer in advance, superimposing the dielectric layer, the adhesive layer, and the conductive layer to form a structure sequentially including the conductive layer, the adhesive layer and the dielectric layer, and hot-pressing the superimposed object.

### 3. Printed Circuit Board

The laminate of the present invention may be used for preparing a printed circuit board. Therefore, the present invention also provides a printed circuit board, which is prepared by further patterning the conductive layer of the aforementioned laminate. The patterning methods include, but are not limited to, etching. The patterning methods are not one of the features of the invention and will not be described in detail.

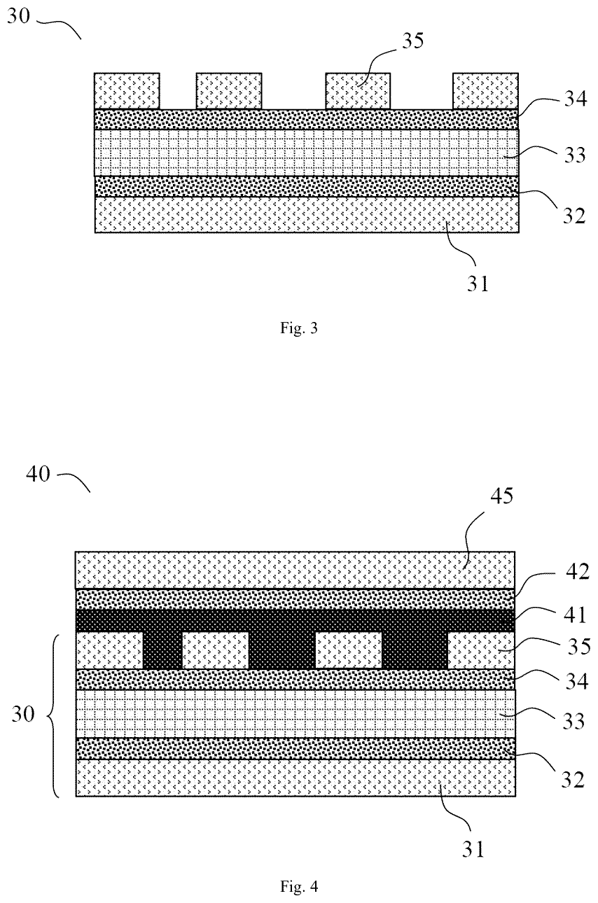

FIG. 3 is a schematic diagram showing an embodiment of the printed circuit board of the present invention. As shown in FIG. 3, the printed circuit board 30 comprises a first conductive layer 31, a first adhesive layer 32, a dielectric layer 33, a second adhesive layer 34, and a patterned second conductive layer 35, wherein the first adhesive layer 32 is disposed between the first conductive layer 31 and the dielectric layer 33, and the second adhesive layer 34 is disposed between the dielectric layer 33 and the patterned second conductive layer 35. The first conductive layer 31 and the patterned second conductive layer 35 may be made of the same or different metal foils, such as the same or different copper foils. The first adhesive layer 32 and the second adhesive layer 34 may be formed from the adhesive compositions of the present invention, using either the same or different formulations. In addition, the printed circuit board 30 can only comprise the first adhesive layer 32 or the second adhesive layer 34.

FIG. 4 is a schematic diagram showing another embodiment of the printed circuit board of the present invention. As shown in FIG. 4, the printed circuit board 40 comprises a first conductive layer 31, a first adhesive layer 32, a dielectric layer 33, a second adhesive layer 34, a patterned second conductive layer 35, a bonding layer 41, a third adhesive layer 42, and a third conductive layer 45, wherein the first adhesive layer 32 is disposed between the first conductive layer 31 and the dielectric layer 33, the second adhesive layer 34 is disposed between the dielectric layer 33 and the patterned second conductive layer 35, and the third adhesive layer 42 is disposed between the bonding layer 41 and the third conductive layer 45. As shown in FIG. 4, the bonding layer 41 and the second adhesive layer 34 are disposed on the opposite sides of the patterned second conductive layer 35, respectively. The third conductive layer 45 and the patterned second conductive layer 35 are disposed on the opposite two sides of the bonding layer 41, respectively. The first conductive layer 31, the patterned second conductive layer 35, and the third conductive layer 45 may be made of the same or different metal foils, such as the same or different copper foils. The first adhesive layer 32, second adhesive layer 34, and third adhesive layer 42 may be formed from the adhesive compositions of the present invention, using either the same or different formulations. In addition, the printed circuit board 40 may exclude the third adhesive layer 42.

### 4. Examples

### 4.1. Testing Methods

The present invention is further illustrated by the embodiments hereinafter, wherein the testing instruments and methods are as follows.

### [Peeling Strength Test]

The peeling strength refers to the adhesion between the metal foil (e.g., copper foil) and the dielectric layer, where the metal-clad laminate was not subjected to any thermal treatment or chemical treatment after the metal-clad laminate is prepared. The peeling strength is expressed by the force required for vertically peeling off a ⅛-inch-wide metal foil from the metal-clad laminate. The unit for the peeling strength is lbf/in.

### [Aging Resistance Test]

The aging resistance is expressed by the peeling strength of the metal-clad laminate after aging treatment, which is also called “aging peeling strength” hereinafter. First, the metal-clad laminate undergoes a process in which it is placed in a dryer at 105° C. for 2 hours to eliminate any moisture present. Subsequently, the metal-clad laminate is removed from the dryer and allowed to naturally cool down to 25° C. inside a desiccator. Then, the dried metal-clad laminate is subjected to an aging treatment in an oven at 177° C. for 10 days. Afterwards, the peeling strength of the treated copper clad laminate is measured using the method as described in the previous section [peeling strength test] to obtain the aging peeling strength. The unit for the aging peeling strength is lbf/in.

### [Peeling Strength Loss Rate]

The peeling strength loss rate is calculated according to the following equation.

$$Peeling strength loss rate = \frac{( Peeling strength - Aging peeling strength )}{Peeling strength} \times 100 \%$$

### [Dielectric Constant (Dk) and Dissipation Factor (Df) Measurement]

First, the adhesive composition is coated onto a copper foil using a coating bar, and the coated copper foil is placed in a hot air circular dryer for a 3-minute thermal treatment at a temperature of 160° C. Subsequently, the copper foil coated with the adhesive composition and a prepreg (model: TU-953, available from Taiwan Union Technology Corporation) are hot-pressed to form a laminate. Afterward, the copper foil of the laminate is etched away to prepare test samples. The Dk and Df of the test samples are measured and calculated according to IPC TM-650 2.5.5.13 at operating frequencies of 10 GHz, 20 GHz and 30 GHz, respectively.

### [Glass Transition Temperature (Tg) Measurement]

First, the adhesive composition is coated onto a copper foil using a coating bar, and the coated copper foil is placed in a hot air circular dryer for a 3-minute thermal treatment at a temperature of 160° C. Subsequently, the copper foil coated with the adhesive composition and a prepreg (model: TU-953, available from Taiwan Union Technology Corporation) are hot-pressed to form a laminate. Afterward, the copper foil of the laminate is etched away to prepare test samples. The Tg of the test samples is measured using a differential scanning calorimeter (DSC). The measuring conditions are as follows: heating from room temperature to 250° C. at a heating rate of 20° C./min, and then cooling to 50° C. at a cooling rate of 20° C./min. The Tg of the test samples is determined based on the obtained DSC curve.

### [Dimensional Stability Test]

First, the adhesive composition is coated onto a copper foil using a coating bar, and the coated copper foil is placed in a hot air circular dryer for a 3-minute thermal treatment at a temperature of 160° C. Subsequently, the copper foil coated with the adhesive composition and a prepreg (model: TU-953, available from Taiwan Union Technology Corporation) are hot-pressed to form a laminate. Afterward, the copper foil of the laminate is etched away to prepare test samples. The coefficients of thermal expansion of the test samples in both the X-axis direction and the Y-axis direction are measured using a thermal mechanical analyzer (TMA). The measuring conditions are as follows: placing the test sample in a heater, heating from room temperature to 250° C. at a heating rate of 20° C./min, and then measuring the CTE of the test samples in both the X-axis direction and the Y-axis direction using a linear displacement sensor. The CTE of the test samples in the X-axis and Y-axis directions represent the dimensional stability of the test sample in the X-axis and Y-axis directions. The unit for the CTE is ppm/° C.

### [Thermal Stability Test]

First, the adhesive composition is coated onto a copper foil using a coating bar, and the coated copper foil is placed in a hot air circular dryer for a 3-minute thermal treatment at a temperature of 160° C. Subsequently, the copper foil coated with the adhesive composition and a prepreg (model: TU-953, available from Taiwan Union Technology Corporation) are hot-pressed to form a laminate. Afterward, the copper foil of the laminate is etched away to prepare test samples. The thermal stability of the test samples is tested using a thermogravimetric analyzer (TGA). The test conditions are as follows: placing the test sample in a heater, heating from room temperature to 400° C. at a heating rate of 10° C./min, and introducing dynamic nitrogen gas. The temperatures at which the test samples experience a 2% weight loss and a 5% weight loss are recorded using a mass balance, thereby indicating the thermal stability of the test samples.

3.2. Table 1: List of raw materials

| Model no. | Description |
|---|---|
| LCOC-5-3 | Cyclic olefin copolymer, concentration: 20 wt %, available from MITSUI |
| | CHEMICALS |
| VI4500 | Cyclic olefin copolymer, available from CHINA PETROLEUM & |
| | CHEMICAL CORPORATION |
| F700 | Acenaphthylene, available from JFE CHEMICAL |
| 185604 | Naphthalene, available from SIGMA |
| P11409 | Phenanthrene, available from SIGMA |
| B34656 | Bipehnyl, available from SIGMA |
| Dynasylan ®1189 | A bifunctional silane with reactive secondary amine and hydrolysable |
| | methoxysilyl, available from EVONIK |
| Dynasylan ®1146 | Diamino functional silane, available from EVONIK |
| Dynasylan ®MEMO | Methacrylic functional silane, available from EVONIK |
| Dynasylan ®VTMO | A bifunctional silane with reactive vinyl and hydrolysable inorganic |
| | trimethoxysilyl, available from EVONIK |
| BFL-NF-Z | Copper foil, thickness: 18 μm, available from CIRCUIT FOIL |
| SI3-VSP CM3R | Copper foil, thickness: 18 μm, available from TAIWAN COPPER FOIL |

### 3.3. Preparation of Adhesive Composition

According to the amounts shown in Table 2-1 and Table 2-2, the polycyclic aromatic hydrocarbon compound (A), the olefin copolymer (B) and the silane coupling agent (C) were mixed using a stirrer at room temperature, and toluene was added as a solvent. Subsequently, the resultant mixture was stirred at room temperature for 30 minutes to obtain Adhesive compositions 1 to 12 and Comparative adhesive compositions 1 to 13.

TABLE 2-1
Compositions of Adhesive compositions 1 to 12

| | | Polycyclic aromatic | | | | Olefin | | Silane coupling agent (C) | | | |
|---|---|---|---|---|---|---|---|---|---|---|---|
| Part by | | hydrocarbon compound (A) | | | | copolymer (B) | | Dynasylan ® | | | |
| weight | | F700 | 185604 | P11409 | B34656 | LCOC-5-3 | VI4500 | 1189 | 1146 | MEMO | VTMO |
| Adhesive | 1 | 35 | | | | 245 | | | 2 | | |
| composition | 2 | 64 | | | | 245 | | | | 2 | |
| | 3 | | 35 | | | 245 | | 1 | | | 1 |
| | 4 | | 64 | | | 245 | | | 3 | | |
| | 5 | | | 35 | | 245 | | 3 | | | |
| | 6 | | | 64 | | 245 | | | | | 3 |
| | 7 | | | | 35 | 245 | | | 2 | | |
| | 8 | | | | 64 | 245 | | | | 3 | |
| | 9 | 47 | | | | 200 | 45 | | 3 | | |
| | 10 | 28 | | | | | 49 | 1.5 | | 1.5 | |
| | 11 | 28 | | | | | 49 | | 3 | | |
| | 12 | 47 | | | | 200 | 45 | 1.5 | | 1.5 | |

TABLE 2-2
Compositions of Comparative adhesive compositions 1 to 13

| | | Polycyclic aromatic | | | | Olefin | | Silane coupling agent (C) | | | |
|---|---|---|---|---|---|---|---|---|---|---|---|
| Part by | | hydrocarbon compound (A) | | | | copolymer (B) | | Dynasylan ® | | | |
| weight | | F700 | 185604 | P11409 | B34656 | LCOC-5-3 | VI4500 | 1189 | 1146 | MEMO | VTMO |
| Comparative | 1 | | | | | | | | | | |
| adhesive | 2 | | | | | 245 | | | 3 | | |
| composition | 3 | 25 | | | | | 49 | | 3 | | |
| | 4 | | 25 | | | 245 | | 1.5 | 1.5 | | |
| | 5 | | | 25 | | 245 | | | | | 3 |
| | 6 | 70 | | | | | | 1.5 | | 1.5 | |
| | 7 | | 70 | | | | | | | | 3 |
| | 8 | | | 70 | | | | 3 | | | |
| | 9 | | | | 25 | 245 | | 1.5 | 1.5 | | |
| | 10 | | | | 70 | | | | 3 | | |
| | 11 | | 25 | | | 200 | 45 | | 1.5 | 1.5 | |
| | 12 | 20 | | | | 245 | | | | | |
| | 13 | | | 20 | | 245 | | | | | |

### 3.4. Preparation of Laminate

Laminates 1 to 20 and Comparative laminates 1 to 24 were prepared by using Adhesive compositions 1 to 12 and Comparative adhesive compositions 1 to 13. First, each of the Adhesive compositions and Comparative adhesive compositions was coated onto a 0.5 oz. copper foil by using a coating bar, and then heated at 160° C. for 3 minutes to form an adhesive layer. The types of the adhesive composition, the types of copper foil, and the thickness of the adhesive layer were shown in Table 3-1 and Table 3-2. Subsequently, a prepreg (model: TU-953, available from Taiwan Union Technology Corporation) was superimposed onto the copper foil on the side with the adhesive layer to provide a superimposed object. Afterward, the superimposed object was subjected to a hot-pressing operation by using a hot-pressing machine to manufacture Laminates 1 to 20 and Comparative laminates 1 to 24. The hot-pressing conditions were as follows: heating to 200° C. to 220° C. at a heating rate of 3.0° C./min, followed by hot-pressing for 240 minutes under a full pressure of 40 kg/cm² (initial pressure is 8 kg/cm²) at 200° C. to 220° C. The properties of Laminates 1 to 20 and Comparative laminates 1 to 24, including peeling strength, aging resistance, peeling strength loss rate, Tg, Dk, Df, dimensional stability, and thermal stability, were tested according to the aforementioned testing methods. The results are tabulated in Table 4-1, Table 4-2, Table 4-3, Table 4-4, Table 4-5, Table 4-6, Table 4-7, and Table 4-8.

TABLE 3-1
Compositions of Laminates 1 to 20

| | | | Copper foil | | Thickness |
|---|---|---|---|---|---|
| | | | | SI3- | of adhesive |
| | | | BFL- | VSP | layer |
| | | Adhesive layer | NF-Z | CM3R | (μm) |
| Laminate | 1 | Adhesive composition 1 | ∨ | | 1.3 |
| | 2 | Adhesive composition 2 | ∨ | | 1.6 |
| | 3 | Adhesive composition 3 | ∨ | | 0.8 |
| | 4 | Adhesive composition 4 | ∨ | | 1.2 |
| | 5 | Adhesive composition 5 | ∨ | | 1.6 |
| | 6 | Adhesive composition 6 | ∨ | | 1.2 |
| | 7 | Adhesive composition 7 | ∨ | | 1.9 |
| | 8 | Adhesive composition 8 | ∨ | | 1.9 |
| | 9 | Adhesive composition 9 | ∨ | | 1.9 |
| | 10 | Adhesive composition 10 | ∨ | | 1.3 |
| | 11 | Adhesive composition 1 | | ∨ | 1.3 |
| | 12 | Adhesive composition 2 | | ∨ | 1.6 |
| | 13 | Adhesive composition 3 | | ∨ | 0.8 |
| | 14 | Adhesive composition 4 | | ∨ | 1.2 |
| | 15 | Adhesive composition 5 | | ∨ | 1.6 |
| | 16 | Adhesive composition 6 | | ∨ | 1.2 |
| | 17 | Adhesive composition 7 | | ∨ | 1.9 |
| | 18 | Adhesive composition 8 | | ∨ | 1.9 |
| | 19 | Adhesive composition 11 | | ∨ | 1.9 |
| | 20 | Adhesive composition 12 | | ∨ | 1.3 |

TABLE 3-2
Compositions of Comparative laminates 1 to 20

| | | | Copper foil | | Thickness |
|---|---|---|---|---|---|
| | | | | SI3-VSP | of adhesive |
| | | Adhesive layer | BFL-NF-Z | CM3R | layer (μm) |
| Comparative | 1 | Comparative adhesive composition 1 | ∨ | | 0 |
| laminate | 2 | Comparative adhesive composition 2 | ∨ | | 1.3 |
| | 3 | Comparative adhesive composition 3 | ∨ | | 1.6 |
| | 4 | Comparative adhesive composition 4 | ∨ | | 1.9 |
| | 5 | Comparative adhesive composition 5 | ∨ | | 1.2 |
| | 6 | Comparative adhesive composition 6 | ∨ | | 0.8 |
| | 7 | Comparative adhesive composition 7 | ∨ | | 0.8 |
| | 8 | Comparative adhesive composition 8 | ∨ | | 0.8 |
| | 9 | Comparative adhesive composition 9 | ∨ | | 1.9 |
| | 10 | Comparative adhesive composition 10 | ∨ | | 0.8 |
| | 11 | Comparative adhesive composition 11 | ∨ | | 1.3 |
| | 12 | Comparative adhesive composition 12 | ∨ | | 1.2 |
| | 13 | Comparative adhesive composition 1 | | ∨ | 0 |
| | 14 | Comparative adhesive composition 2 | | ∨ | 1.3 |
| | 15 | Comparative adhesive composition 3 | | ∨ | 1.6 |
| | 16 | Comparative adhesive composition 4 | | ∨ | 1.9 |
| | 17 | Comparative adhesive composition 5 | | ∨ | 1.2 |
| | 18 | Comparative adhesive composition 6 | | ∨ | 0.8 |
| | 19 | Comparative adhesive composition 7 | | ∨ | 0.8 |
| | 20 | Comparative adhesive composition 8 | | ∨ | 0.8 |
| | 21 | Comparative adhesive composition 9 | | ∨ | 1.9 |
| | 22 | Comparative adhesive composition 10 | | ∨ | 0.8 |
| | 23 | Comparative adhesive composition 11 | | ∨ | 1.3 |
| | 24 | Comparative adhesive composition 13 | | ∨ | 1.3 |

TABLE 4-1
Properties of Laminates 1 to 5

| | | Laminate | | | | |
|---|---|---|---|---|---|---|
| | Unit | 1 | 2 | 3 | 4 | 5 |
| Peeling strength | lbf/in | 3.09 | 3.40 | 2.69 | 2.94 | 2.99 |
| Aging resistance | lbf/in | 2.51 | 2.83 | 1.94 | 1.84 | 2.41 |
| Peeling strength loss rate | | 18.77% | 16.76% | 27.88% | 37.41% | 19.40% |
| Dk @ 10 GHz | | 3.20 | 3.21 | 2.96 | 2.85 | 3.18 |
| Df @ 10 GHz | | 0.0014 | 0.0013 | 0.0014 | 0.0014 | 0.0015 |
| Dk @ 20 GHz | | 3.20 | 3.18 | 2.92 | 2.84 | 3.15 |
| Df @ 20 GHz | | 0.0015 | 0.0016 | 0.0014 | 0.0014 | 0.0017 |
| Dk @ 30 GHz | | 3.19 | 3.19 | 2.95 | 2.87 | 3.18 |
| Df @ 30 GHz | | 0.0018 | 0.0018 | 0.0016 | 0.0016 | 0.0018 |
| Tg | ° C. | 161 | 181 | 193 | 185 | 160 |
| X-axis CTE | ppm/° C. | 23 | 23 | 19 | 15 | 25 |
| Y-axis CTE | ppm/° C. | 24 | 24 | 22 | 20 | 26 |
| 2% weight loss | ° C. | 361 | 366 | 360 | 362 | 360 |
| 5% weight loss | ° C. | 389 | 394 | 388 | 390 | 392 |

TABLE 4-2
Properties of Laminates 6 to 10

| | | Laminate | | | | |
|---|---|---|---|---|---|---|
| | Unit | 6 | 7 | 8 | 9 | 10 |
| Peeling strength | lbf/in | 2.55 | 3.80 | 4.43 | 3.74 | 3.08 |
| Aging resistance | lbf/in | 2.22 | 2.59 | 2.97 | 3.19 | 2.54 |
| Peeling strength loss rate | | 12.94% | 31.84% | 32.96% | 14.71% | 17.53% |
| Dk @ 10 GHz | | 3.24 | 2.95 | 3.04 | 3.18 | 3.15 |
| Df @ 10 GHz | | 0.0013 | 0.0014 | 0.0014 | 0.0013 | 0.0013 |
| Dk @ 20 GHz | | 3.24 | 2.95 | 3.04 | 3.18 | 3.15 |
| Df @ 20 GHz | | 0.0015 | 0.0014 | 0.0014 | 0.0016 | 0.0015 |
| Dk @ 30 GHz | | 3.24 | 2.97 | 3.06 | 3.20 | 3.14 |
| Df @ 30 GHz | | 0.0017 | 0.0017 | 0.0018 | 0.0017 | 0.0018 |
| Tg | ° C. | 166 | 197 | 167 | 199 | 163 |
| X-axis CTE | ppm/° C. | 26 | 21 | 25 | 25 | 22 |
| Y-axis CTE | ppm/° C. | 26 | 22 | 25 | 24 | 22 |
| 2% weight loss | ° C. | 357 | 362 | 363 | 367 | 358 |
| 5% weight loss | ° C. | 384 | 387 | 394 | 395 | 385 |

TABLE 4-3
Properties of Laminates 11 to 15

| | | Laminate | | | | |
|---|---|---|---|---|---|---|
| | Unit | 11 | 12 | 13 | 14 | 15 |
| Peeling strength | lbf/in | 3.18 | 2.54 | 3.32 | 2.84 | 3.29 |
| Aging resistance | lbf/in | 2.65 | 2.05 | 2.68 | 2.29 | 2.74 |
| Peeling strength loss rate | | 16.67% | 19.29% | 19.28% | 19.37% | 16.72% |
| Dk @ 10 GHz | | 3.22 | 3.12 | 2.97 | 2.99 | 3.23 |
| Df @ 10 GHz | | 0.0014 | 0.0013 | 0.0014 | 0.0014 | 0.0014 |
| Dk @ 20 GHz | | 3.22 | 3.12 | 2.94 | 2.96 | 3.20 |
| Df @ 20 GHz | | 0.0016 | 0.0015 | 0.0014 | 0.0014 | 0.0017 |
| Dk @ 30 GHz | | 3.21 | 3.12 | 2.96 | 2.99 | 3.22 |
| Df @ 30 GHz | | 0.0019 | 0.0018 | 0.0015 | 0.0016 | 0.0018 |
| Tg | ° C. | 157 | 161 | 172 | 184 | 170 |
| X-axis CTE | ppm/° C. | 23 | 24 | 24 | 16 | 25 |
| Y-axis CTE | ppm/° C. | 23 | 24 | 23 | 22 | 25 |
| 2% weight loss | ° C. | 361 | 361 | 358 | 358 | 360 |
| 5% weight loss | ° C. | 387 | 387 | 386 | 386 | 390 |

TABLE 4-4
Properties of Laminates 16 to 20

| | | Laminate | | | | |
|---|---|---|---|---|---|---|
| | Unit | 16 | 17 | 18 | 19 | 20 |
| Peeling strength | lbf/in | 2.69 | 3.65 | 4.92 | 2.54 | 2.55 |
| Aging resistance | lbf/in | 2.23 | 2.61 | 3.16 | 2.13 | 2.22 |
| Peeling strength loss rate | | 17.10% | 28.49% | 35.77% | 16.14% | 12.94% |
| Dk @ 10 GHz | | 3.20 | 2.99 | 3.02 | 3.23 | 3.19 |
| Df @ 10 GHz | | 0.0013 | 0.0014 | 0.0014 | 0.0013 | 0.0013 |
| Dk @ 20 GHz | | 3.18 | 2.96 | 2.97 | 3.22 | 3.18 |
| Df @ 20 GHz | | 0.0016 | 0.0014 | 0.0015 | 0.0015 | 0.0015 |
| Dk @ 30 GHz | | 3.20 | 2.99 | 3.00 | 3.21 | 3.18 |
| Df @ 30 GHz | | 0.0017 | 0.0018 | 0.0019 | 0.0018 | 0.0018 |
| Tg | ° C. | 199 | 194 | 167 | 152 | 160 |
| X-axis CTE | ppm/° C. | 25 | 19 | 25 | 24 | 22 |
| Y-axis CTE | ppm/° C. | 24 | 19 | 25 | 23 | 23 |
| 2% weight loss | ° C. | 367 | 361 | 366 | 359 | 364 |
| 5% weight loss | ° C. | 394 | 387 | 394 | 385 | 390 |

TABLE 4-5
Properties of Comparative laminates 1 to 6

| | | Comparative laminate | | | | | |
|---|---|---|---|---|---|---|---|
| | Unit | 1 | 2 | 3 | 4 | 5 | 6 |
| Peeling strength | lbf/in | 2.49 | 2.79 | 2.81 | 2.94 | 2.98 | 2.18 |
| Aging resistance | lbf/in | 0.27 | 1.05 | 1.55 | 1.66 | 1.45 | 0.75 |
| Peeling strength loss rate | | 89.16% | 62.37% | 44.84% | 43.54% | 51.34% | 65.60% |
| Dk @ 10 GHz | | 3.25 | 3.19 | 3.21 | 3.16 | 3.20 | 3.22 |
| Df @ 10 GHz | | 0.0013 | 0.0013 | 0.0013 | 0.0013 | 0.0013 | 0.0013 |
| Dk @ 20 GHz | | 3.25 | 3.18 | 3.19 | 3.15 | 3.20 | 3.21 |
| Df @ 20 GHz | | 0.0015 | 0.0015 | 0.0015 | 0.0015 | 0.0015 | 0.0016 |
| Dk @ 30 GHz | | 3.24 | 3.17 | 3.21 | 3.14 | 3.20 | 3.22 |
| Df @ 30 GHz | | 0.0018 | 0.0018 | 0.0018 | 0.0018 | 0.0018 | 0.0019 |
| Tg | ° C. | 157 | 156 | 171 | 163 | 155 | 166 |
| X-axis CTE | ppm/° C. | 28 | 22 | 20 | 23 | 23 | 21 |
| Y-axis CTE | ppm/° C. | 24 | 22 | 21 | 23 | 23 | 27 |
| 2% weight loss | ° C. | 363 | 365 | 358 | 358 | 360 | 359 |
| 5% weight loss | ° C. | 390 | 387 | 384 | 385 | 386 | 386 |

TABLE 4-6
Properties of Comparative laminates 7 to 12

| | | Comparative laminate | | | | | |
|---|---|---|---|---|---|---|---|
| | Unit | 7 | 8 | 9 | 10 | 11 | 12 |
| Peeling strength | lbf/in | 2.29 | 2.29 | 3.55 | 2.35 | 2.67 | 2.73 |
| Aging resistance | lbf/in | 0.47 | 0.92 | 0.89 | 0.59 | 1.26 | 0.54 |
| Peeling strength loss rate | | 79.48% | 59.83% | 74.93% | 74.89% | 52.81% | 80.22% |
| Dk @ 10 GHz | | 2.97 | 3.24 | 3.07 | 2.98 | 3.14 | 3.24 |
| Df @ 10 GHz | | 0.0014 | 0.0013 | 0.0013 | 0.0013 | 0.0013 | 0.0013 |
| Dk @ 20 GHz | | 2.93 | 3.22 | 3.05 | 2.96 | 3.13 | 3.22 |
| Df @ 20 GHz | | 0.0014 | 0.0014 | 0.0014 | 0.0015 | 0.0015 | 0.0015 |
| Dk @ 30 GHz | | 2.95 | 3.23 | 3.07 | 2.98 | 3.13 | 3.23 |
| Df @ 30 GHz | | 0.0017 | 0.0018 | 0.0018 | 0.0018 | 0.0018 | 0.0018 |
| Tg | ° C. | 167 | 155 | 200 | 213 | 171 | 169 |
| X-axis CTE | ppm/° C. | 19 | 31 | 22 | 21 | 24 | 23 |
| Y-axis CTE | ppm/° C. | 16 | 21 | 22 | 23 | 23 | 24 |
| 2% weight loss | ° C. | 360 | 360 | 358 | 359 | 365 | 365 |
| 5% weight loss | ° C. | 388 | 387 | 384 | 386 | 392 | 392 |

TABLE 4-7
Properties of Comparative laminates 13 to 18

| | | Comparative laminate | | | | | |
|---|---|---|---|---|---|---|---|
| | Unit | 13 | 14 | 15 | 16 | 17 | 18 |
| Peeling strength | lbf/in | 2.30 | 2.73 | 2.88 | 2.44 | 2.25 | 1.74 |
| Aging resistance | lbf/in | 0.47 | 0.94 | 1.68 | 1.32 | 1.26 | 0.86 |
| Peeling strength loss rate | | 79.57% | 65.57% | 41.67% | 45.90% | 44.00% | 50.57% |
| Dk @ 10 GHz | | 3.21 | 3.13 | 3.18 | 3.21 | 3.18 | 3.11 |
| Df @ 10 GHz | | 0.0014 | 0.0012 | 0.0014 | 0.0014 | 0.0014 | 0.0014 |
| Dk @ 20 GHz | | 3.21 | 3.09 | 3.18 | 3.18 | 3.18 | 3.10 |
| Df @ 20 GHz | | 0.0016 | 0.0015 | 0.0015 | 0.0016 | 0.0015 | 0.0016 |
| Dk @ 30 GHz | | 3.21 | 3.11 | 3.18 | 3.19 | 3.18 | 3.09 |
| Df @ 30 GHz | | 0.0018 | 0.0016 | 0.0018 | 0.0018 | 0.0018 | 0.0019 |
| Tg | ° C. | 159 | 157 | 158 | 162 | 217 | 161 |
| X-axis CTE | ppm/° C. | 25 | 24 | 23 | 27 | 24 | 24 |
| Y-axis CTE | ppm/° C. | 23 | 24 | 22 | 27 | 22 | 23 |
| 2% weight loss | ° C. | 361 | 361 | 364 | 363 | 365 | 362 |
| 5% weight loss | ° C. | 387 | 387 | 390 | 391 | 391 | 389 |

TABLE 4-8
Properties of Comparative laminates 19 to 24

| | | Comparative laminate | | | | | |
|---|---|---|---|---|---|---|---|
| | Unit | 19 | 20 | 21 | 22 | 23 | 24 |
| Peeling strength | lbf/in | 2.25 | 2.29 | 3.24 | 2.26 | 2.84 | 2.49 |
| Aging resistance | lbf/in | 1.31 | 1.33 | 0.89 | 0.89 | 1.29 | 0.46 |
| Peeling strength loss rate | | 41.78% | 41.92% | 72.53% | 60.62% | 54.58% | 81.53% |
| Dk @ 10 GHz | | 2.98 | 3.23 | 3.04 | 2.97 | 3.18 | 3.18 |
| Df @ 10 GHz | | 0.0014 | 0.0014 | 0.0013 | 0.0015 | 0.0015 | 0.0013 |
| Dk @ 20 GHz | | 2.94 | 3.20 | 3.06 | 2.95 | 3.15 | 3.25 |
| Df @ 20 GHz | | 0.0014 | 0.0017 | 0.0014 | 0.0017 | 0.0017 | 0.0015 |
| Dk @ 30 GHz | | 2.96 | 3.22 | 3.03 | 2.96 | 3.18 | 3.24 |
| Df @ 30 GHz | | 0.0016 | 0.0018 | 0.0018 | 0.0019 | 0.0018 | 0.0018 |
| Tg | ° C. | 198 | 170 | 198 | 206 | 169 | 172 |
| X-axis CTE | ppm/° C. | 26 | 25 | 23 | 26 | 25 | 28 |
| Y-axis CTE | ppm/° C. | 25 | 25 | 25 | 26 | 26 | 24 |
| 2% weight loss | ° C. | 359 | 360 | 359 | 361 | 360 | 383 |
| 5% weight loss | ° C. | 386 | 390 | 386 | 387 | 392 | 410 |

As shown in Table 4-1, Table 4-2, Table 4-3, and Table 4-4, the results of Laminates 1 to 20 show that the adhesive composition of the present invention effectively enhances the adhesion strength between the conductive layer and the dielectric layer. This allows for an improvement in the peeling strength and aging resistance of the resultant laminate without adversely affecting its dielectric properties, thermal resistance and dimensional stability. In addition, from the comparison between Laminates 1 to 8 and Laminates 11 to 18, it can be seen that even when different copper foils are used, as long as the adhesive layer is the adhesive composition of the present invention, the resultant laminate exhibits good dielectric properties, thermal resistance, dimensional stability, peeling strength and aging resistance.

In contrast, as shown in Table 4-5, Table 4-6, Table 4-7, and Table 4-8, the adhesive composition not belonging to the present invention is unable to effectively enhance the adhesion strength and aging resistance of the laminate. Comparative laminates 1 and 13 show that when the laminate does not include an adhesive layer, the laminate exhibits extremely poor peeling strength. Comparative laminates 2 and 14 show that when the adhesive composition does not contain the polycyclic aromatic hydrocarbon compound (A), the resultant laminate exhibits poor aging resistance. Comparative laminates 6 to 8, 10, 18 to 20 and 22 show that when the adhesive composition does not contain the olefin copolymer (B), the resultant laminate exhibits poor aging resistance. Comparative laminates 12 and 24 show that when the adhesive composition does not contain the silane coupling agent (C), the resultant laminate exhibits poor aging resistance. Comparative laminates 3 to 5, 9, 11, 15 to 17, 21 and 23 show that when the amount of the polycyclic aromatic hydrocarbon compound (A) falls outside the specified range, the resultant laminate exhibits poor aging resistance.

The above examples are used to illustrate the principle and efficacy of the present invention and show the inventive features thereof, but are not used to limit the scope of the present invention. People skilled in this field may proceed with a variety of modifications and replacements based on the disclosures and suggestions of the invention as described. Therefore, the scope of protection of the present invention is that as defined in the claims as appended.

### BRIEF DESCRIPTION OF NUMERAL REFERENCES

10, 20: laminate
11: conductive layer
13, 23, 33: dielectric layer
12: adhesive layer
22, 32: first adhesive layer
21, 31: first conductive layer
24, 34: second adhesive layer
25, 35: second conductive layer
30, 40: printed circuit board
41: bonding layer
42: third adhesive layer
45: third conductive layer

What is claimed is:

1. An adhesive composition, comprising the following components:
(A) a polycyclic aromatic hydrocarbon compound;
(B) an olefin copolymer, which comprises the following repeating units:
(B-1) a repeating unit represented by the following formula (I), 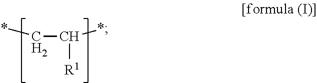
(B-2) a repeating unit represented by the following formula (II), 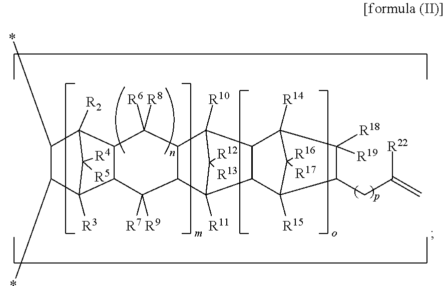
and
(B-3) a repeating unit represented by the following formula (III), 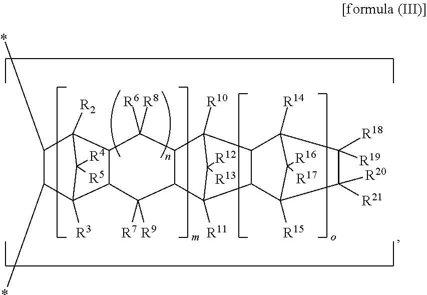
in formulas (I) to (III),
R¹ is H or a C1 to C29 linear or branched hydrocarbon group;
R² to R²¹ are independently H, halogen, a C1 to C20 alkyl, a C1 to C20 halogenated alkyl, a C3 to C15 cycloalkyl, or a C6 to C20 aryl, and R¹⁸ to R²¹ may form a monocyclic ring or polycyclic ring by binding to each other;
R²² is H or a C1 to C10 alkyl;
m and n are independently 0 or 1;
o is 0 or a positive integer;
p is 0 or a positive integer ranging from 1 to 10; and
in formula (III), when both m and n are 0, at least one of R¹⁰ to R¹³ and R¹⁸ to R²¹ is not H; and
(C) a silane coupling agent,
wherein,
based on the total moles of the repeating units (B-1), (B-2) and (B-3), the amount of the repeating unit (B-2) ranges from 1 mol % to less than 100 mol %; and
based on the total weight of the polycyclic aromatic hydrocarbon compound (A), the olefin copolymer (B) and the silane coupling agent (C), the amount of the polycyclic aromatic hydrocarbon compound (A) ranges from 33 wt % to 64 wt %, the amount of the olefin copolymer (B) ranges from 35 wt % to 66 wt %, and the amount of the silane coupling agent (C) ranges from 0.1 wt % to 4.0 wt %.

2. The adhesive composition of claim 1, wherein the polycyclic aromatic hydrocarbon compound (A) is selected from the group consisting of acenaphthylene, biphenyl, naphthalene, anthracene, phenanthrene, pyrene, benzo[a]pyrene, benzo[e]pyrene, indeno[1,2,3-cd]pyrene, benzo[a]anthracene, fluoranthene, benzo[b]fluoranthene, benzo[g,h,i]fluoranthene, benzo[j]fluoranthene, benzo[k]fluoranthene, chrysene, 5-methylchrysene, dibenzo[a,h]anthracene, perylene, benzo[g,h,i]perylene, acenaphthene, fluorene, ovalene, and combinations thereof.

3. The adhesive composition of claim 1, wherein the polycyclic aromatic hydrocarbon compound (A) has from two to ten aromatic rings.

4. The adhesive composition of claim 1, wherein based on the total weight of the polycyclic aromatic hydrocarbon compound (A), the olefin copolymer (B) and the silane coupling agent (C), the amount of the polycyclic aromatic hydrocarbon compound (A) ranges from 34 wt % to 56 wt %.

5. The adhesive composition of claim 1, wherein R¹ is H or a C1 to C6 alkyl.

6. The adhesive composition of claim 1, wherein the repeating unit (B-2) is formed by addition copolymerization of one or more cyclic non-conjugated diene monomers, wherein the one or more cyclic non-conjugated diene monomers are selected from the group consisting of 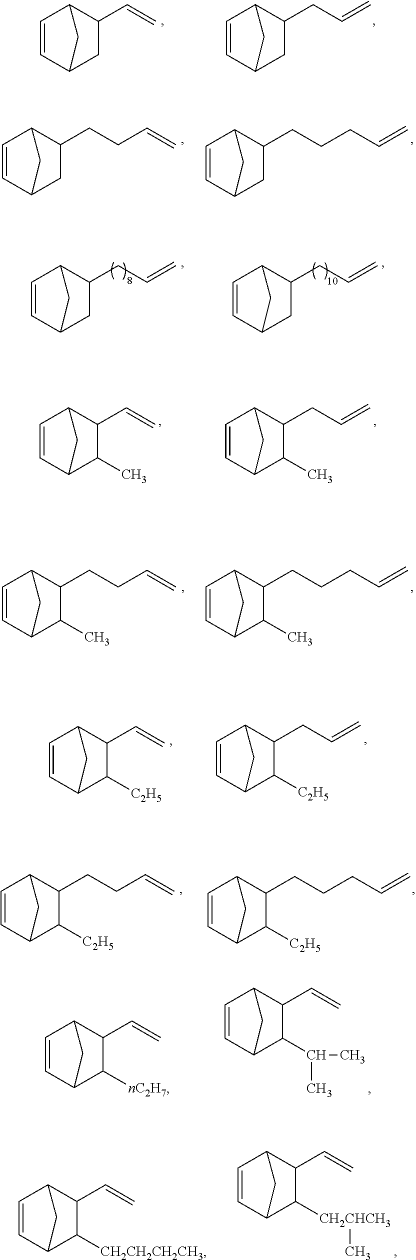 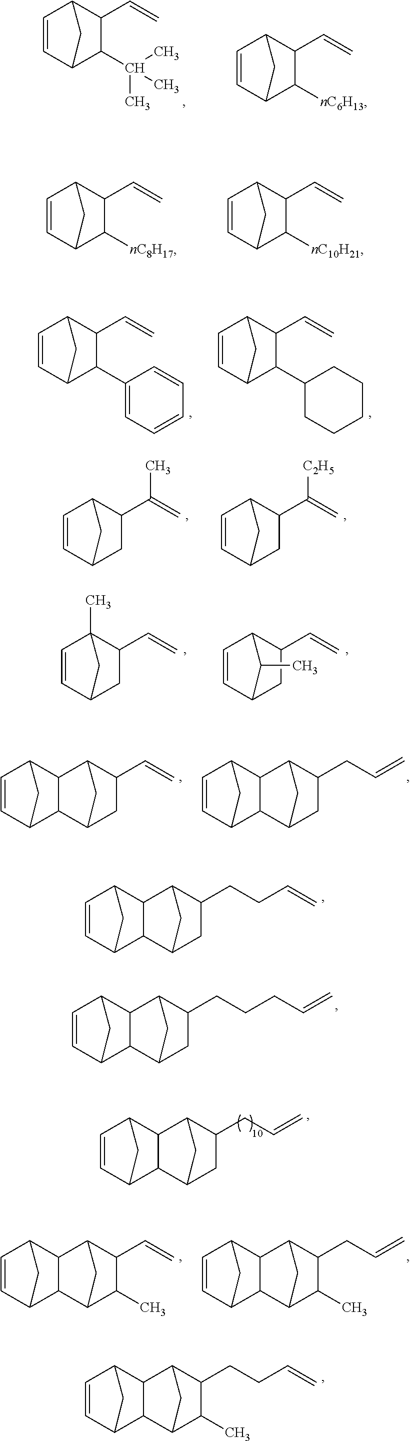 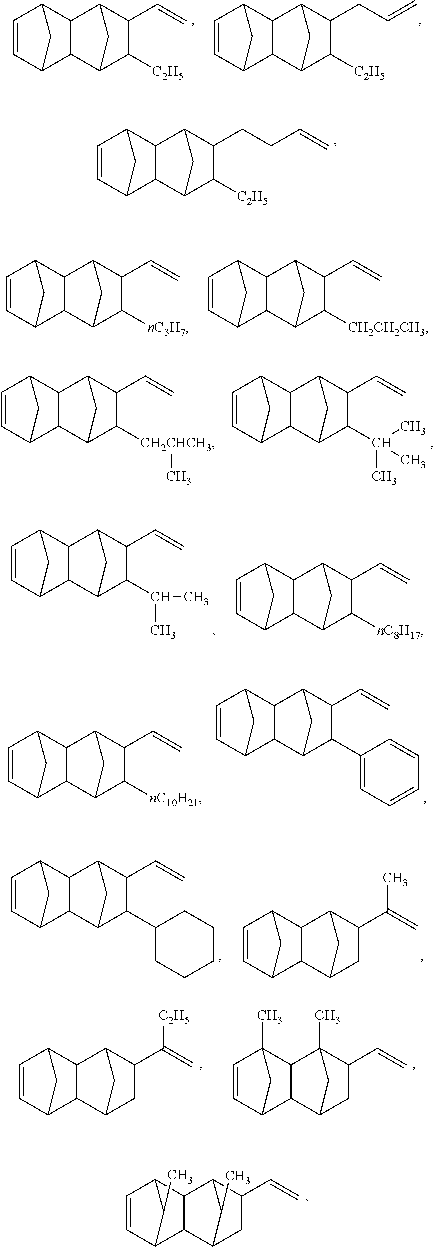
and combinations thereof.

7. The adhesive composition of claim 1, wherein based on the total moles of the repeating units (B-1), (B-2) and (B-3), the amount of the repeating unit (B-2) ranges from 19 mol % to 36 mol %.

8. The adhesive composition of claim 1, wherein based on the total weight of the polycyclic aromatic hydrocarbon compound (A), the olefin copolymer (B) and the silane coupling agent (C), the amount of the olefin copolymer (B) ranges from 42 wt % to 65 wt %.

9. The adhesive composition of claim 2, wherein based on the total weight of the polycyclic aromatic hydrocarbon compound (A), the olefin copolymer (B) and the silane coupling agent (C), the amount of the olefin copolymer (B) ranges from 42 wt % to 65 wt %.

10. The adhesive composition of claim 1, wherein the silane coupling agent (C) is an amino silane coupling agent.

11. The adhesive composition of claim 2, wherein the silane coupling agent (C) is an amino silane coupling agent.

12. The adhesive composition of claim 1, wherein the silane coupling agent (C) is selected from the group consisting of N-(2-aminoethyl)-3-aminopropyl trimethoxy silane, N-(n-butyl)-3-aminopropyl trimethoxy silane, N-phenyl-3-aminopropyl trimethoxy silane, 3-methacryloxy propyl trimethoxy silane, 4-epoxypropyl butyl trimethoxy silane, vinyl trimethoxy silane, vinyl phenyl trimethoxy silane, 3-mercaptopropyl methyl dimethoxy silane, 3-mercaptopropyl trimethoxy silane, tetraethoxysilane, and combinations thereof.

13. The adhesive composition of claim 2, wherein the silane coupling agent (C) is selected from the group consisting of N-(2-aminoethyl)-3-aminopropyl trimethoxy silane, N-(n-butyl)-3-aminopropyl trimethoxy silane, N-phenyl-3-aminopropyl trimethoxy silane, 3-methacryloxy propyl trimethoxy silane, 4-epoxypropyl butyl trimethoxy silane, vinyl trimethoxy silane, vinyl phenyl trimethoxy silane, 3-mercaptopropyl methyl dimethoxy silane, 3-mercaptopropyl trimethoxy silane, tetraethoxysilane, and combinations thereof.

14. The adhesive composition of claim 1, wherein based on the total weight of the polycyclic aromatic hydrocarbon compound (A), the olefin copolymer (B) and the silane coupling agent (C), the amount of the silane coupling agent (C) ranges from 2.0 wt % to 4.0 wt %.

15. The adhesive composition of claim 2, wherein based on the total weight of the polycyclic aromatic hydrocarbon compound (A), the olefin copolymer (B) and the silane coupling agent (C), the amount of the silane coupling agent (C) ranges from 2.0 wt % to 4.0 wt %.

16. A laminate, which comprises:
a dielectric layer;
an adhesive layer disposed on at least one side of the dielectric layer; and
a conductive layer disposed on the other side of the adhesive layer opposite to the dielectric layer,
wherein the adhesive layer is formed from the adhesive composition of claim 1.

17. The laminate of claim 16, wherein the conductive layer is a copper foil.

18. The laminate of claim 16, wherein the dielectric layer is prepared from one or more prepregs, wherein each of the prepregs comprises a curable resin and a reinforcing material.

19. The laminate of claim 18, wherein the curable resin is selected from the group consisting of polyphenylene ether resins, epoxy resins, phenolic resins, polyformaldehyde resins, silicones, multi-functional vinyl aromatic copolymers, polytetrafluoroethylene, and combinations thereof.

20. A printed circuit board, which is prepared from the laminate of claim 16.
